(19) United States
(12) Patent Application Publication
(10) Pub. No.: US 2009/0284932 A1
(43) Pub. Date: Nov. 19, 2009

(54) Thermally Enhanced Package with Embedded Metal Slug and Patterned Circuitry

(75) Inventor: Charles W.C. LIN, Yunghe (TW)

Correspondence Address: David M. Sigmond, 10 Anson Road #47-14, Singapore, 079903, SG

(73) Assignee: Bridge Semiconductor Corporation, Taipei (TW)

(21) Appl. No.: 12/406,510

(22) Filed: Mar. 18, 2009

Related U.S. Application Data
(60) Provisional application No. 61/064,748, filed on Mar. 25, 2008.
(60) Provisional application No. 61/071,072, filed on Apr. 11, 2008.
(60) Provisional application No. 61/071,588, filed on May 7, 2008.
(60) Provisional application No. 61/071,589, filed on May 7, 2008.

(51) Int. Cl. H05K 7/20

(52) U.S. Cl. 361/718

(57) ABSTRACT

The present invention thermally enhanced package with embedded metal slug and patterned circuitry discloses a thermal enhanced package with an embedded metal slug that can be easy directly assembled to the printed circuit board to significantly improve package's thermal dissipation efficiency through the assistance of metal traces in the application board.

### TECHNICAL FIELD OF THE INVENTION

The present invention is directed, in general to semiconductor packaging, and more specifically, to a thermally enhanced semiconductor package with an embedded solid metal slug and patterned circuitry.

### BACKGROUND OF THE INVENTION

High voltage and high frequency applications normally require substantial amount of power to perform specific functions. As power increases, the semiconductor chip's temperature would increase accordingly if the thermal management of the device were not properly designed. Drawbacks of this high temperature operation includes performing at lower speeds, exhibits non-ideal operating characteristics and relatively shorter operating life span. Furthermore, the less than desirable performances can be aggravated by the trend of miniaturization as there is less surface area to dissipate the heat away since chips and passives are placed closely together in the package or module for accommodating a smallest possible profile.

In order to achieve the desired performances for high power IC devices, the designer needs to ensure that the semiconductor package is capable of dissipating a large amount of heat and this would largely depend upon the heat-carrying characteristics of the package and thermal management strategies.

Plastic packages such as ball grid array packages (PBGA) are built using laminate-based substrates and the heat dissipation of these packages are mainly through the fiber glass and dielectric material in the laminate substrate to the solder balls and then to the attached printed circuit board (PCB). However, since fiber glass and plastics have very low thermal conductivity and provide poor characteristics in both heat conduction and heat spreading and hence plastic BGA have relatively poor thermal performances.

FIG. 1 describes a typical Quad-Flat-No Lead (QFN) package in which the semiconductor chip is attached to the die pad, which in turn is soldered to the PCB directly to enhance its thermal spreading function. Since the heat conduction includes copper die pad and the attached printed circuit board, QFN packages in general exhibit better thermal characteristics than that of the PBGA. However, due to the limited routing capabilities of lead-frame type interposer, QFN is unable to accommodate high I/O devices (for example, more than 100) and suffers from many assembly difficulties when trying to accommodate passive elements therein.

To achieve similar thermal characteristics for plastic laminate package, U.S. Pat. No. 6,670,219 discloses a thermal enhanced package wherein a heat sink and a ground plate are adhered together to form the thermal dissipating substrate. As shown in FIG. 2, a cavity is formed in a central portion of the substrate to allow chip contacts the heat spreader of the package for a better thermal dissipation. However, this “cavity-down” ball grid array (CDBGA) configuration suffers a major drawback in that the heat spreader doesn't contact the printed circuit board directly when assembled. As such, the primary heat dissipation mechanism becomes thermal convection instead of thermal conduction and that mechanism greatly limits the heat spreading and dissipation efficiency. Furthermore, passive assembly is also being constrained due to the heat spreader spanning across one side of the package and solder balls from the other side.

U.S. Pat. No. 6,528,882 discloses a thermal enhanced ball grid array package wherein a metal core layer is enclosed in the substrate to enhance the thermal performance. As shown in FIG. 3, even though the internal thermal pathway can be improved due to direct attachment of the chip to the metal core, the thermal insulation layer deposited on the bottom surface of the metal core causes considerable heat resistance that reduces the thermal performance of the package.

U.S. Pat. No. 7,038,311 disclose a thermal enhanced ball grid array package wherein a plastic substrate having an opening therethrough is covered by a metal slug. As shown in FIG. 4, this metal slug serves as the die paddle and can be soldered to the PCB directly for the improvement of thermal performance. Since the generated heat can be directly conducted to the PCB through the high thermal conductivity metal slug and solder balls, this construction displays a desired thermal performance equivalent to that of a QFN. However, the drop-in metal slug normally induces an un-even substrate surfaces, and this non-planar issue often cause tremendous difficulties in chip assembly especially die bonding, wire bonding and molding, and therefore suffers reliability, yield loss and significant higher cost problems.

Prior arts disclosed in U.S. Pat. No. 6,900,535, U.S. Pat. No. 6,541,832, and U.S. Pat. No. 6,507,102 etc., provides solutions wherein the drop-in metal slug is adjusted to essentially the same level as the terminal leads. As shown in FIG. 5, this approach still suffers from many challenges in terms of assembly cost and package reliability. For example, during metal slug attachment, it is not easy to achieve a consistent bond line for good reliability as this requires void free bonding with very tight lateral (x-y) placement tolerance. The reason for the poor reliability is that the inserted metal slug does not provide rigidity support for the cavity-opened substrate, and the partial attachment makes the substrate becomes fragmental. Furthermore, the differences in the thermal expansion coefficients among metal slug, laminate substrate, and molding compound can result in potential de-lamination at the interfaces. This in turns results in ingression of moisture into the molded plastic package that leads to corrosion and posing a serious threat to reliability of integrated circuits.

Considering the deficiencies of the above-mentioned prior arts, it would be desirable for a plastic laminate package to perform equivalent or better thermal characteristics to QFN, can accommodate high I/O devices or module, having high package reliability, low cost and does not require expensive tooling of the substrate and heat spreader.

### SUMMARY OF THE INVENTION

The present invention discloses a thermal enhanced package with an embedded metal slug that can be directly assembled to the printed circuit board to significantly improves package's thermal dissipation efficiency through the assistance of metal traces in the application board.

It is another object of the present invention to provide a thermal enhanced package whereby the embedded metal slug and terminal leads are portion of a single piece of metal. This single metal structure ensures high package reliability and enables a planar bottom surface for high assembling yield.

It is yet another object of the present invention to provide a thermal enhanced package wherein the multiple routing layers enclosed in the substrate allow multiple chips to be packaged in conjunction with multiple passive elements.

One aspect of the invention is the flexibility of the package interface with the application board; the options include package designs as land grid array, ball grid array, or pin grid array.

The technical advances represented by the invention, as well as the aspects thereof, will become apparent from the following description of the preferred embodiments of the invention, when considered in conjunction with the accompanying drawings, thermal performance and the novel features set forth in the appended claims.

### BRIEF DESCRIPTION OF THE DRAWINGS

FIG. 1 illustrates schematic cross-sectional views of the conventional Quad-Flat-No Lead (QFN) packages

FIG. 2-5 illustrates schematic cross-sectional views of the conventional thermal enhanced ball grid array packages

FIG. 6 is a schematic, cross-sectional view of a thermal enhanced package according to the preferred embodiment of the present invention. As the semiconductor chip is depicted with its integrated circuit (IC) facing upwards relative to the connection to the application board, it is therefore referred to as a “cavity up” package.

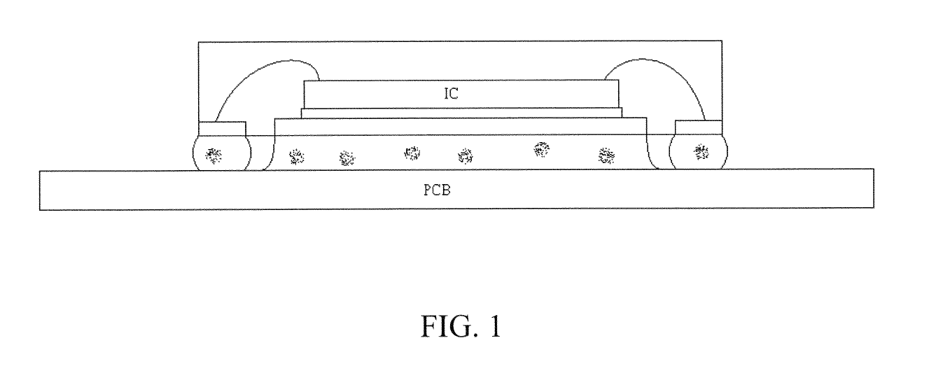

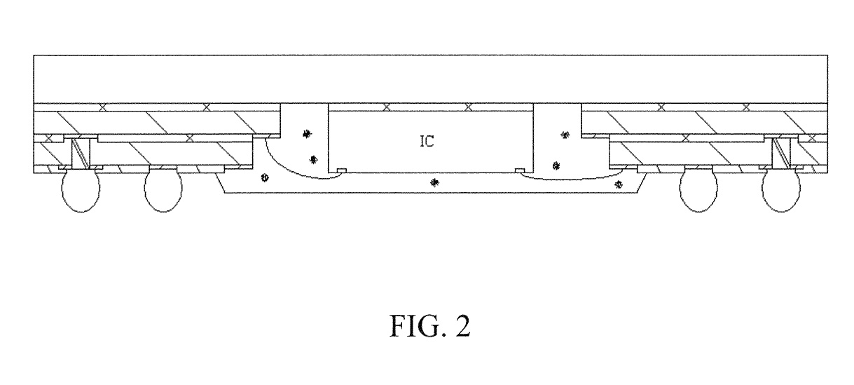

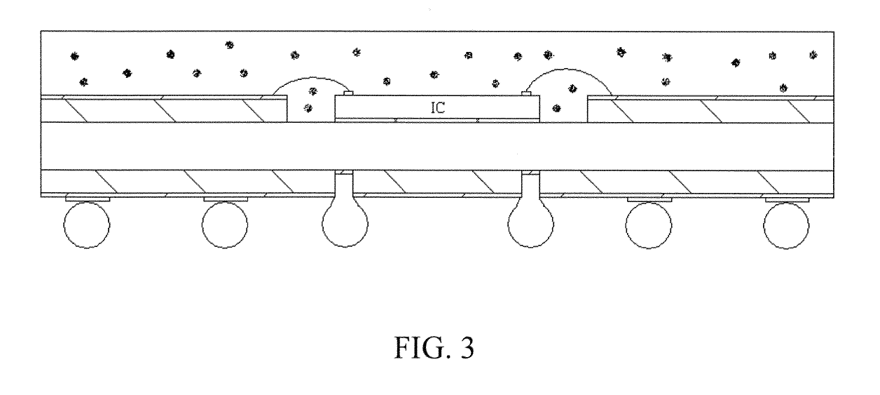

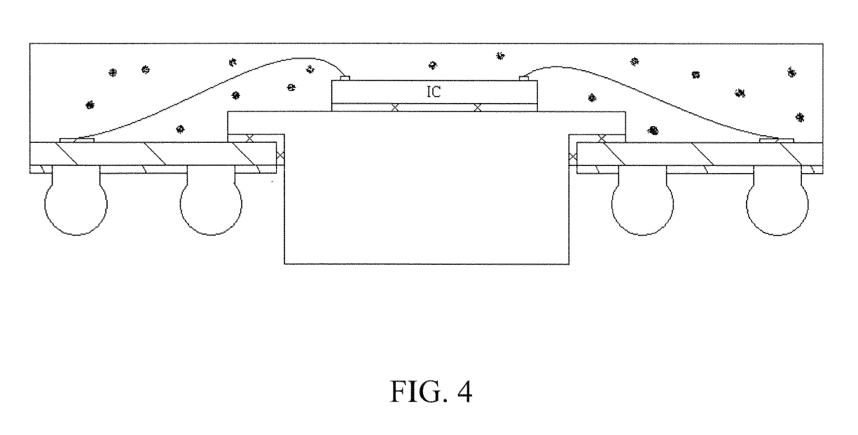

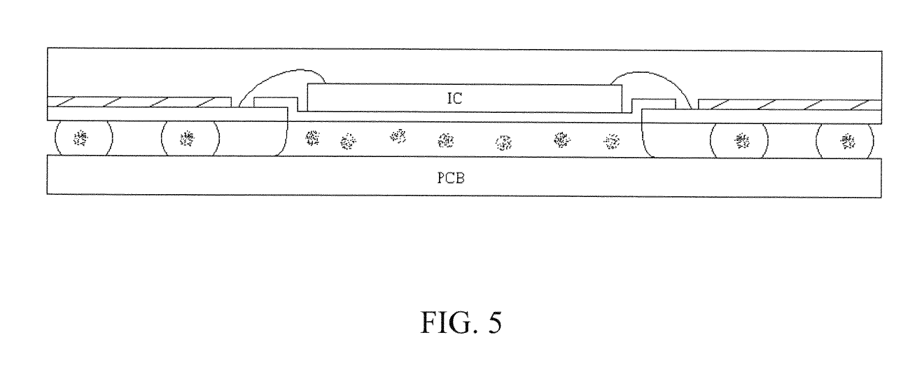

### DETAILED DESCRIPTION OF THE PREFERRED EMBODIMENTS

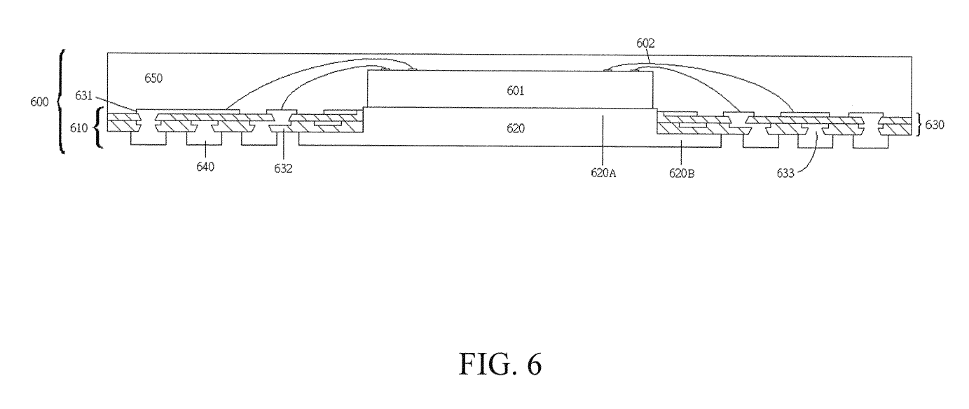

As shown in FIG. 6, the thermal enhanced package designated 600, comprises a substrate 610 that includes an embedded metal slug 620, a patterned circuitry 630, and a plurality of terminal leads 640.

A pivotal part of the package of the present invention is the embedded metal slug 620 in the substrate 610. In the preferred embodiment, the embedded metal slug 620 consists of a die pad portion 620A and a thermal pad portion 620B. The die pad portion 620A exposed from the upper surface of the substrate 610 and the thermal pad portion 620B exposed from the bottom surface of the substrate 610. An essential feature of the embedded metal slug 620 is that the exposed surface area of the thermal pad portion 620B is larger than that of the die paddle portion 620A. This configuration allows the heat generated from the semiconductor chip can be transferred to the die pad and quickly spread out to a much larger area for effective thermal dissipation. The exposed surface of the die pad portion 620A is typically deposited with a combination of metal layers such as nickel/palladium/gold for a better die attachment interface. Likewise, the exposed surface of thermal pad portion 620B is deposited with a similar combination of metal for solderable finishing purpose.

As shown in FIG. 6, the patterned circuitry 630, consisting of at least one conductor layer 631 and at least one dielectric layer 632 alternatively stacked on one another, is provided in a region adjacent to the die pad portion 620A and on the upper surface of the thermal pad portion 620B and terminal leads 640. The patterned circuitry 630 is adhered to the die pad portion 620A through the dielectrics 632 to ensure embedded metal slug 620 is securely bonded to the substrate 610 vertically and horizontally. A plurality of metallized via holes 633 in the dielectric layer 632 is provided to electrically connect the patterned circuitry 630 to the terminal leads 640. The metallized via holes 633 can also connect the patterned circuitry 630 to the embedded metal slug 620 through thermal pad portion 620B when electrical grounding or power is needed.

The dielectric layer 632 can include epoxy resin, glass epoxy resin, Ajinomoto build-up film (ABF) or bismaleimide-triazine (BT) resin. A commercially available substrate such as FR-4 substrate, FR-5 substrate and BT substrate can be used as the dielectric layer, if desired. The via hole 633 can be formed by laser ablating or through hole drilling. The laser used typically includes gas laser, solid laser, such as carbon dioxide laser, yttrium-aluminum-garnet laser (YAG laser).

A plurality of terminal leads 640, which is made of the same material as embedded metal slug 620 is formed on the lower portion of the substrate 610 for signal input/output purpose. It is essential for the present invention that the terminal leads 640 are horizontally aligned with the thermal pad 620B disposed on the bottom surface of the substrate 610. This co-planarity feature is naturally formed since they are made of a single piece of metal. Thus, no additional concerns would add to the production process. The co-planarity of the thermal pad 620B with the terminal leads 640 is essential not only for package reliability and proper board level assembly, but also to ensure that when under operation, the heat generated from IC can freely flow through the die pad portion 620A to the larger thermal pad portion 620B before dispersed to the metal traces in the application board (not shown). This configuration provides an extremely short thermal path and the largest possible contact area therefore ensures an excellent heat dissipating efficiency of the package.

As used herein, the term “terminal lead” is to serve as connection to other parts or to printed circuit board and does not imply that the contacts are necessarily in a specific shape. They may have various forms, such as land, ball, pillar, pin, post, semispherical, truncated cone, or generally bump. The exact shape is a function of the formation technique (such as etching, plating) and soldering technique (such as infrared or radiant heat).

The attachment of chip 601 is typically performed with a conductive paste, heat conductive tape or soft solder, which is standard in semiconductor technology.

The semiconductor chip 601 includes the plurality of bonding pads (not shown) are wire bonded 602 to the conductor layer 631 integral with the patterned circuitry 630. Wire bonding 602 is the preferred method of using coupling members to create electrical interconnections between the plurality of chip bonding pads and the conductor layer 631. Other methods such as flip chip bonding and ribbon bonding can be applied as well.

In this package configuration, each terminal lead 640 is electrically connected with one specific via hole 633, and one specific conductor line 631, which is in turn connected to one specific bond pad of the integrated circuit die 601 through one specific wire bond 602, and thus functions as an input/output for the packaged device.

The chip 601, the wire bond 602, and the substrate 610 are encapsulated with a molding compound 650. If needed, a heat sink can be further provided on the surface of the chip 601 or molding compound 650 to further increase the heat dissipation and performance of a package.

While this invention has been described in reference to illustrative embodiments, this description is not intended to be construed in a limiting sense. Various modifications changes, substitutions, variations, enhancements, gradations, lesser forms, alterations, revisions and improvements of the invention disclosed herein may be made without departing from the spirit and scope of the invention in its broadest form. As an example, the finishing of bottom surface of die pad and terminal leads may comprise gold, nickel, silver, palladium, tin, solders or any other soldering material used in manufacturing. As another example, the number of patterned conductor layer 631 in the patterned circuitry 630 used for signal routing may include multiple layers, thus provides a multi-level substrate for a flexible design in package.

What is claimed is:

1. A thermal enhanced package, comprising:
a substrate, including:
an embedded metal slug includes a die pad portion and a thermal pad portion wherein said die pad portion exposed from the top surface of said substrate and said thermal pad portion exposed from the bottom surface of said substrate; and
a plurality of terminal leads formed over the bottom surface of said substrate; and
a patterned circuitry includes at least one conductor layer and at least one dielectric layer alternatively stacked on one another, is provided on the upper surface of said thermal pad portion and said terminal leads; and
at least one metallized via hole is provided in said patterned circuitry for electrical connection of said conductor layer to said terminal leads; and
an integrated circuit die mounted over the exposed surface of said die pad portion having bond wires electrically connected to said patterned circuitry; and
an encapsulating material over said integrated circuit die, said bond wires, and said substrate.

2. The thermal enhanced package of claim 1, wherein said thermal pad is horizontally level with said terminal leads.

3. The thermal enhanced package of claim 1, wherein the exposed surface of said thermal pad portion is larger than the exposed surface of said die pad portion.

4. The thermal enhanced package of claim 1, wherein said embedded metal slug and said terminal leads are the integral portion of a single metal.

5. The thermal enhanced package of claim 1, wherein said metallized via hole can connect said patterned circuitry to said thermal pad for grounding purpose.
